(19) United States
(12) Patent Application Publication
(10) Pub. No.: US 2022/0201802 A1
(43) Pub. Date: Jun. 23, 2022

(54) Heater Assembly and Encapsulation Method

(71) Applicant: nVent Services GmbH, Schaffhausen (CH)

(72) Inventors: Artur Koziol, Dzierzoniow (PL); Arkadiusz Cichocki, Wroclaw (PL); Wojciech Tuchorski, Dzierzoniow (PL)

(21) Appl. No.: 17/556,172

(22) Filed: Dec. 20, 2021

Related U.S. Application Data
(60) Provisional application No. 63/130,091, filed on Dec. 23, 2020.

(51) Int. Cl. H05B 3/04; B29C 39/38; B29C 39/10; H05B 3/56

(52) U.S. Cl. CPC H05B 3/04; B29C 39/38; B29L 2031/779; H05B 3/56; B29C 39/10

(57) ABSTRACT

A heater assembly with a pre-encapsulated heating element and a method of producing the pre-encapsulated heating element are provided. The heater assembly can include a channel defining an interior space and a pre-encapsulated heating element. The pre-encapsulated heating element can include a resistive heating element having a pre-encapsulated portion that is surrounded by a block of potting compound. The pre-encapsulated portion can be received with the interior space of the channel.

### CROSS-REFERENCE TO RELATED APPLICATIONS

The application claims the benefit of U.S. Provisional Patent Application 63/130,091, filed Dec. 23, 2020, and entitled “Heater Assembly and Heating Cable Encapsulation Methods,” which is incorporated herein by reference in its entirety.

### BACKGROUND

Electronics modules such as temperature controllers are commonly housed in or on weatherproof enclosures and used in outdoor environments. In extreme environments, temperatures may reach as low as −55 degrees, Celsius (° C.) or even colder. Electronic components, however, are usually only rated for operation in temperatures of −40° C. or warmer and may malfunction or even suffer permanent damage if operated at excessively low temperatures. Thus, to enable operation at very low temperatures, some enclosures may require electric heater assemblies to preheat and/or maintain the electronics at a safe operating temperature.

### SUMMARY

Embodiments of the invention provide for a heater assembly having a pre-encapsulated heating element and a method for producing a pre-encapsulated heating element.

According to one embodiment of the invention, a heater assembly for heating an electrical device is provided. The heater assembly can include a channel defining an interior space and a pre-encapsulated heating element. The pre-encapsulated heating element can include a resistive heating element with a pre-encapsulated portion that can be surrounded by a block of potting compound. The pre-encapsulated portion can be configured to be received within the interior space of the channel.

In some embodiments, the channel can define a channel width and the pre-encapsulated portion can define a pre-encapsulated heating element width. A ratio of the pre-encapsulated heating element width to the channel width can be between 1.01 and 1.05. Accordingly, an interference fit between the pre-encapsulated portion and the channel can cause the pre-encapsulated portion to be compressed by the channel so that the pre-encapsulated heating element is secured within the channel. Relatedly, in some embodiments, the channel can include opposing parallel sides that define the interior space of the channel. More specifically, the channel can have a U-shaped cross section.

In some embodiments, the potting compound can be a thermal transfer compound that is configured to transfer heat from the resistive heating element to the channel to heat the electrical device. For example, the potting compound can be a two-part polyurethane compound. The resistive heating element can be configured as a heating cable, and more specifically, a self-regulating heating cable or a constant wattage heating cable. Alternatively, the resistive heating element can be configured as a cartridge heater.

In some embodiments, the resistive heating element can be a plurality of resistive heating elements. Relatedly, the channel can be one of a plurality of channels and the pre-encapsulated heating element can include a plurality of pre-encapsulated portions. Each of the plurality of pre-encapsulated portions can be received within a corresponding channel of the plurality of channels.

According to another embodiment of the invention, a method of producing a pre-encapsulated heating element for a heater assembly is provided. The method can include the steps of assembling a mold that defines a cavity, securing a portion of a resistive heating element within the cavity of the mold, inserting a sealing insert into an end hole of the mold to position the resistive heating element within the mold, adding a potting compound to the mold to fully surround the portion of the resistive heating element that is secured within the mold, allowing the potting compound to cure within the mold to form an encapsulated portion of the pre-encapsulated heating element, and removing the encapsulated portion from the mold. The mold can include a first mold part defining a first portion of the cavity and a second mold part defining a second portion of the cavity. Accordingly, the first mold part and the second mold part can be coupled together to form the cavity.

In some embodiments, the method can further include the step of removing any excess portions of cured potting compound from the pre-encapsulated portion. Relatedly, the step of allowing the potting compound to cure can include applying heat to the mold. In that regard, the mold can include a mold heating element configured to apply heat to the mold. The mold heating element can be a cartridge heater.

In some embodiments, the mold can define a bleed hole and the potting compound can be added to the mold until the potting compound begins to flow out of the cavity through the bleed hole. The cavity can define a width that is larger than a corresponding width of a channel of the heater assembly.

According to another embodiment of the invention, a heater assembly is provided that includes channels, each defining a channel width, and a pre-encapsulated heating element. The pre-encapsulated heating element can include a resistive heating element having encapsulated portions, each surrounded by a block of potting compound. Each of the encapsulated portions can be received within a corresponding channel and can define an encapsulated portion width. The encapsulated portion width can be greater than the channel width of the corresponding channel.

### DESCRIPTION OF THE DRAWINGS

FIG. 1 is a front, internal view of an electronics enclosure.

FIG. 2 is an isometric view of a DIN rail heater assembly including encapsulated heater cables, according to some embodiments.

FIG. 3 is a cross-sectional view of the DIN rail heater assembly of FIG. 2.

FIG. 4 is an isometric view of a panel heater assembly including encapsulated heater cables, according to some embodiments.

FIG. 5 is a cross-sectional view of a solid state relay heater assembly including encapsulated heater cables, according to some embodiments.

FIG. 6 is an isometric view of a part of a mold for encapsulating heater cables, according to some embodiments.

FIG. 7 is an isometric view of the mold part of FIG. 6, including a heater cable routed therethrough.

FIG. 8 is an isometric view of the mold part of FIG. 6, including a cartridge heater routed beside a cavity of the mold part.

FIG. 9 is an isometric view of a mold, according to some embodiments, including the mold part of FIG. 5.

FIG. 10 is an exploded view of the mold of FIG. 9.

FIG. 11 is a partial isometric view of encapsulated heating cables, according to some embodiments upon release from the mold of FIG. 9.

FIG. 12 is an isometric view of encapsulated heating cables according to some embodiments.

FIG. 13 is an isometric view of the encapsulated heating cables of FIG. 11 being installed in the solid state relay heater assembly of FIG. 5.

FIG. 14 is schematic view of a method for encapsulating a heater cable, according to some embodiments.

### DETAILED DESCRIPTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

The following discussion is presented to enable a person skilled in the art to make and use embodiments of the invention. Various modifications to the illustrated embodiments will be readily apparent to those skilled in the art, and the generic principles herein can be applied to other embodiments and applications without departing from embodiments of the invention. Thus, embodiments of the invention are not intended to be limited to embodiments shown, but are to be accorded the widest scope consistent with the principles and features disclosed herein. The following detailed description is to be read with reference to the figures, in which like elements in different figures have like reference numerals. The figures, which are not necessarily to scale, depict selected embodiments and are not intended to limit the scope of embodiments of the invention. Skilled artisans will recognize the examples provided herein have many useful alternatives and fall within the scope of embodiments of the invention.

Numeric ranges disclosed herein are inclusive of their endpoints. For example, a numeric range of between 1 and 10 includes the values 1 and 10. When a series of numeric ranges are disclosed for a given value, embodiments of the invention contemplates ranges including all combinations of the upper and lower bounds of those ranges. For example, a numeric range of between 1 and 10 or between 2 and 9 is intended to include the numeric ranges of between 1 and 9 and between 2 and 10.

Embodiments of the invention are generally directed toward heater assemblies incorporating heating cables, and a manufacturing process for pre-encapsulating a heating cable for such assemblies. The manufacturing process results in the heating cable becoming a subcomponent of the heater assembly, including one or more portions being encapsulated (e.g., surrounded) by a thermally conductive material, for example, a solid piece of molded polyurethane (PU) compound. The pre-encapsulated heating cable can then be installed in a final heater assembly. The encapsulated portions of the heating cable can include external dimensions that correlate with dimensions (e.g., any suitable of a width, height, length, diameter, etc.) of a slot or cable channel of the heater assembly, e.g., associated with a heat sink. More specifically, the encapsulated portion can be slightly wider than a corresponding channel width, thus providing a proper compression ratio of the encapsulated portion when pushed into the channel to ensure proper contact along a length of the channel for optimal heat transfer from the heating cable, through the PU, to the heat sink. In this way, the interference or compression fit between the encapsulated portion of the heating cable can also help to retain the heating cable within the channel.

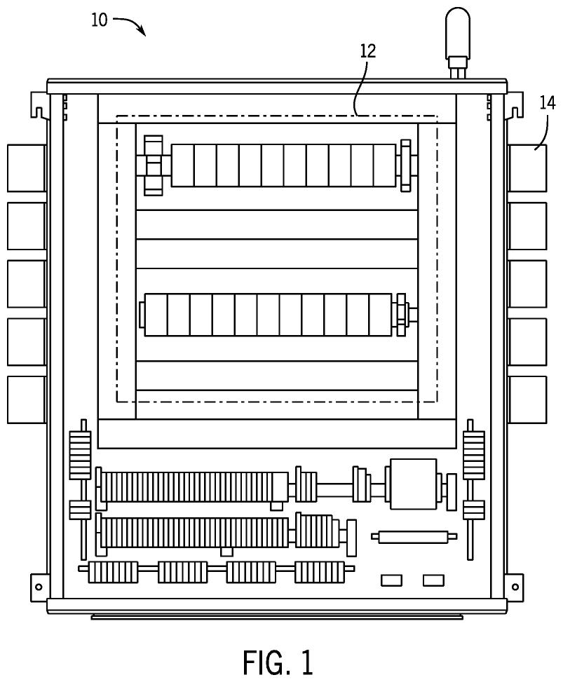

FIG. 1 illustrates an enclosure 10 (i.e., an electronics enclosure) configured to mount electronic equipment. The enclosure 10 can support electronic devices 12 (i.e., electrically-powered equipment and/or devices) internally, such as internally mounted temperature controllers, wire terminals, or other electronics, as well as support electronics externally, such as externally mounted solid state relay (SSR) assemblies 14. In some applications, this type of enclosure 10 may be used in certain environments, such as arctic environments or oil platform environments. These environments often encounter extreme temperatures (e.g., below −40° C.) that may cause malfunctions or reduced performance in electronic devices 12 (e.g., SSR assemblies 14), supported by the enclosure 10. That is, such electronic devices 12 (e.g., SSR assemblies 14) may not be rated to withstand such cold temperatures. As a result, the enclosure 10 can include one or more heater assemblies incorporating one or more pre-encapsulated heating elements, such as heating cables (e.g., self-regulating heating cables or constant wattage heating cables), cartridge heaters, and other types of resistive heating elements configured to heat the electronics to a rated operating temperature. In that regard, while the discussion below may only refer to, for example, a heating cable or a cartridge heater, it is not to be interpreted as being limited to just that type of heating element. For example, discussion of a heating cable may be equally applicable to other embodiments using a heating cartridge, and vice versa.

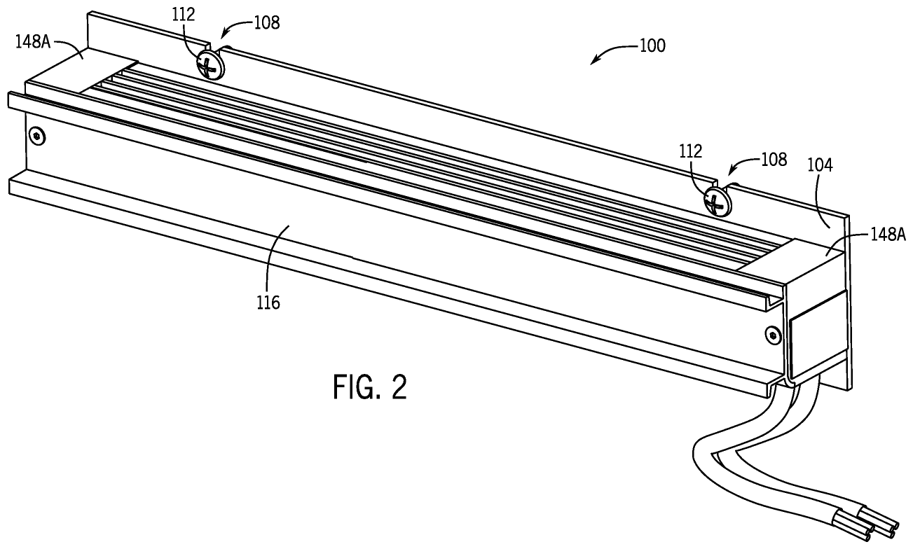

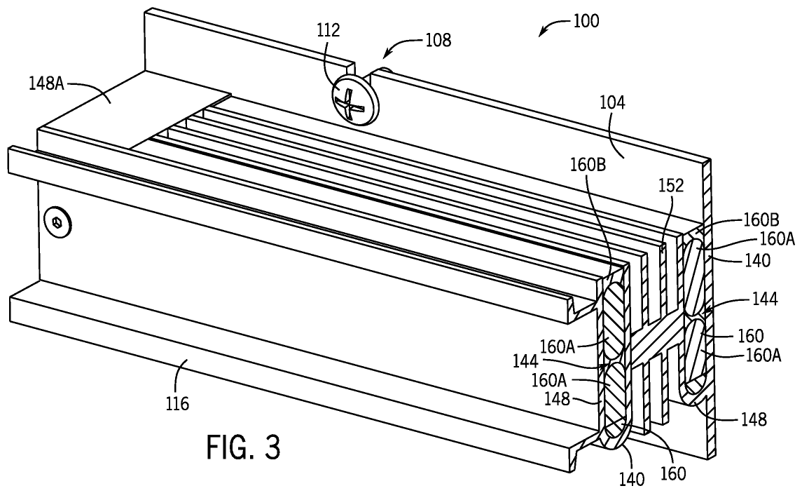

For example, FIGS. 2 and 3 illustrate an example heater assembly 100 according to embodiments of the invention, which can be used to heat electronic devices. More specifically, the heater assembly 100 is configured as an internal heater assembly that can be used with an enclosure, such as the enclosure 10 illustrated in FIG. 1. The heater assembly 100 generally includes a mounting rail 104 (e.g., a custom-formed or standardized mounting rail) configured to be mounted to the enclosure 10 and, more specifically, a wall (e.g., an internal wall or internal side of an outer wall) of the enclosure 10. In that regard, the heater assembly 100 can include one or more mounting features (i.e., mounting structures) to allow the heater assembly 100 to be coupled to the enclosure 10. As illustrated, the mounting rail 104 includes a plurality of slots 108 that can be configured to receive a corresponding plurality of fasteners 112.

The heater assembly 100 can serve as an intermediate structure to support one or more electronic devices. In that regard, the heater assembly 100 can include mounting features or structures that are configured to couple to and support electronic devices. In some applications, it may be preferrable that the heater assembly 100 incorporate standardized mounting structures for supporting one or more electronic devices. For example, as illustrated, the heater assembly 100 includes a DIN rail 116 for mounting electronic equipment (e.g., temperature controllers, wire terminals, etc.).

In addition to supporting one or more electronic devices a heater assembly can also be configured to support a heating element that can provide heat to any supported electronic devices. For example, as shown in FIG. 3, the DIN rail 116 can define one or more slots or channels 140 that can be configured to receive a heating element. More specifically, a channel 140 defines an interior space 144 between opposing channel walls 148, which can be configured to receive and support a heating element therein. As illustrated, the heater assembly 100 includes a pair of channels 140 each defining a corresponding interior space 144 between U-shaped channel walls 148. The channels 140 are separated by a plurality of fins 152, which can serve to radiate heat from the heating elements, each of which is configured as a pre-encapsulated heating element, such as a pre-encapsulated heating cable or pre-encapsulated cartridge heater. As illustrated, the pre-encapsulated heating element is configured as a pre-encapsulated heating cable 160 (e.g., a pre-encapsulated heating cable subcomponent). Accordingly, the heater assembly 100 can provide localized heating to electronic equipment mounted on the DIN rails 116. Features and additional designs of such heater assemblies are described in more detail in U.S. patent application Ser. No. 16/791,813, filed Feb. 14, 2020, the entire contents of which is incorporated herein by reference. In other embodiments, more than one pre-encapsulated heating cable can be used.

A pre-encapsulated heating cable or other pre-encapsulated heating element can generally include one or more heating elements (e.g., resistive heating elements including resistive heating cables and cartridge heaters) that are surrounded along at least a portion of their respective lengths by an encapsulating block, thereby defining an encapsulated portion. In some cases, one or more heating cables can be surrounded by one or more encapsulating blocks to form a corresponding number of encapsulated portions. Each encapsulating block can extend along a respective portion of a length of the respective heating elements.

In the illustrated embodiment, the pre-encapsulated heating cable 160 includes two resistive heating cables 160A, and two encapsulating blocks 160B extending along respective portions of the pre-encapsulated heating cable 160. More specifically, the encapsulating blocks 160B extend along each of the portions of the resistive heating cable 160A that are disposed within the channels 140 so that the encapsulated portions are disposed within the channels 140. Accordingly, as will be described in greater detail below, the encapsulating blocks 160B can be configured to retain and secure the pre-encapsulated heating cable 160 or other pre-encapsulated heating element within the respective channels 140 (e.g., via a press- or interference-fit connection). Relatedly, the encapsulating blocks 160B can provide for improved heat transfer between the resistive heating cable 160A and the heater assembly 100. In other embodiments, a pre-encapsulated heating cable can be configured differently. For example, a pre-encapsulated heating cable can include more or less resistive heating cables and/or more or less encapsulating blocks.

Furthermore, in some embodiments, a heater assembly can include caps or guards configured to protect a pre-encapsulated heating cable. For example, in the illustrated embodiment, the heater assembly 100 includes end caps 148A (e.g., a pair of end caps) disposed on opposing ends of the channels 140. The end caps 148A are configured to protect the exposed ends of the pre-encapsulated heating cables 160, since the channels 140 are open at each respective end. In that regard, in some embodiments, the end caps 148A can serve as end walls for the channels 140. Additionally, depending on the specific implementation, each end cap 148A can be identically configured, or they can be configured differently from one another.

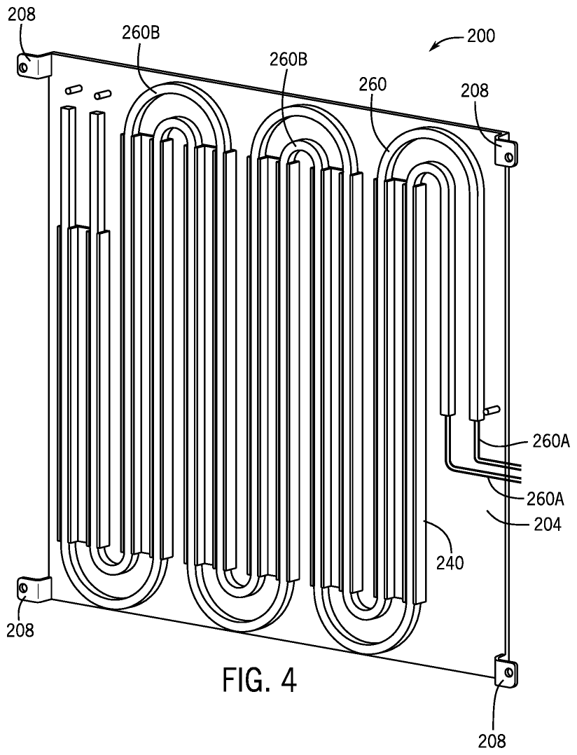

As shown in FIG. 4, another example heater assembly 200 is illustrated according to aspects of the invention. The heater assembly 200 includes a mounting plate 204 having a rectangular shape, but other suitable shapes of plates are possible. The mounting plate 204 can be configured to be mounted to an enclosure for electronic devices, for example, the enclosure 10, and to support electronic devices thereon. In that regard, the heater assembly 200 can include one or more mounting structures, which can be configured to allow the heater assembly 200 to be secured to a support structure. For example, as illustrated, the heater assembly 200 includes a plurality of feet 208, which can be configured to receive a corresponding plurality of fasteners.

The heater assembly 200 further includes a plurality of channels 240, which are similar to channels 140 and are configured to receive one or more heating elements configured as pre-encapsulated heating cables. The channels 240, are illustrated as being generally spaced apart (e.g., evenly spaced) in substantially parallel rows along the mounting plate 204. The channels are configured to receive two pre-encapsulated heating cables 260, although more or less heating cables can be provided in other embodiments. Accordingly, the pre-encapsulated heating cables 260 can also be arranged so that they are parallel to one another along their respective lengths. In this way, the heater assembly 200 can provide more even heating to the entire mounting plate 204. In other embodiments, the channels 240 and the respective pre-encapsulated heating cables 260 can be configured differently. For example, the channels 240 may not be arranged in rows, or they may only extend along a portion of the mounting plate 204. Alternatively, or additionally, the channels 240 and the respective pre-encapsulated heating cables 260 may not be evenly spaced. Accordingly, the channels 240 and the pre-encapsulated heating cables 260 can be configured to provide areas of localized heating or areas with localized areas of elevated temperature.

Each of the pre-encapsulated heating cables 260 includes resistive heating cables 260A and an encapsulating block 260B. Here, the encapsulating blocks 260B are configured to extend between and through multiple channels and the size (e.g., a length and/or width) of each of the encapsulating blocks 260B corresponds with respective channels 240 in which the encapsulating block 260B is received. In other embodiments, the pre-encapsulated heating cable 260 can be configured differently. For example, the pre-encapsulated heating cables 260 can each include a plurality of encapsulating blocks 260B that are configured to extend through a specific channel. More specifically, in the illustrated embodiment, each pre-encapsulated heating cable 260 can include six encapsulating blocks 260B that are secured within a corresponding channel 240.

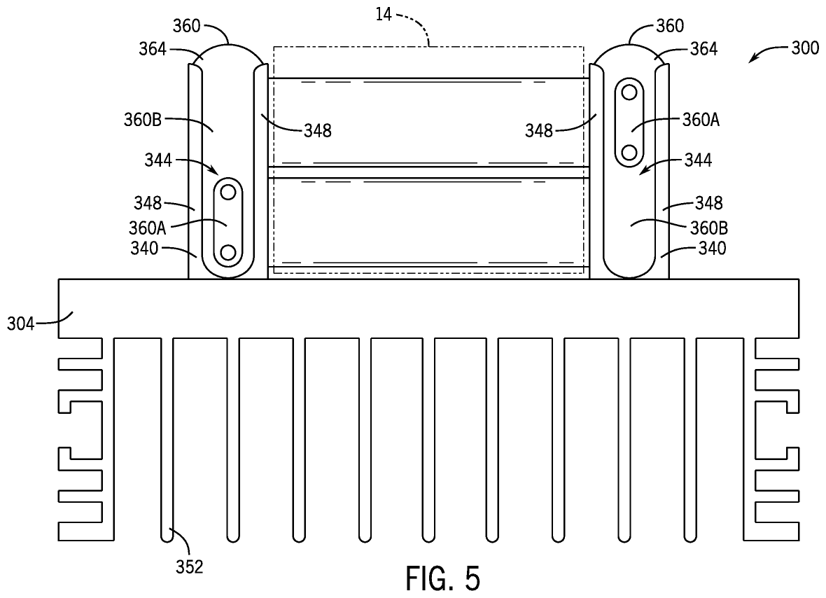

FIG. 5 illustrates another example heater assembly 300 according to embodiments of the invention. The heater assembly 300 is configured as a solid-state relay (SSR) heater assembly (e.g., a custom-formed SSR heater assembly) that can be mounted to the enclosure 10. The heater assembly 300 includes an SSR mounting plate or platform 304 that is configured to couple to and support one or more SSRs (see e.g., SSR assemblies 14, as shown in FIG. 1). The heater assembly 300 can further include channels 340 and a plurality of fins 352 supported on opposing sides of the SSR mounting platform 304. The fins 352 and the channels 340 extend generally away from one another. The channels 340 define interior spaces 344 that can be configured to receive a pre-encapsulated heating cable 360, thus providing localized heating to any SSRs installed on the SSR mounting platform 304. More specifically, the channels 340 are spaced apart and extend parallel to one another to allow one or more SSRs to be coupled to the heater assembly between the channels 340. In this way, heat generated by the pre-encapsulated heating cable 360 can be transferred to the SSRs to maintain the SSRs at or above a desired temperature (e.g., a minimum operating temperature).

Similar to the other embodiments described above, the pre-encapsulated heating cable 360 includes resistive heating elements configured as resistive heating cables 360A. As illustrated the pre-encapsulated heating cable 360 includes two resistive heating cables 360A, which are stacked within the channels 340 so that one of the resistive heating cables 360A is disposed closer to the SSR mounting platform 304 than the other. In other embodiments, any included resistive heating cables can be arranged differently, which may help to achieve a desired amount of heat production.

The portions of the resistive heating cables 360A that extend through each of the channels 340 are pre-encapsulated with encapsulating blocks 360B, whereas the portions of the resistive heating cables 360A extending between respective channels 340 are not encapsulated. Additionally, as illustrated the encapsulating blocks 360B can be configured to extend beyond (i.e., outside of) the channels 340. More specifically, the encapsulating blocks 360B can define lips 364 that are configured to engage with the channel walls 348 of the channels 340 when the pre-encapsulated heating cable 360 is fully-inserted into the respective channel 340. In other embodiments, the resistive heating cables 360A can be configured differently, for example, the resistive heating cables 360A may not be encapsulated at all or they may be encapsulated along an entire length of the respective cable (e.g., so that both the portions of the heating cable within the channels and the portions of the cable extending outside the channels are encapsulated.

As generally discussed above, heater assemblies (e.g., heater assemblies 100, 200, 300) can include one or more channels (e.g. channels 140, 240, 340) that can be configured to receive a portion of a pre-encapsulated heating cable. For example, as illustrated in FIGS. 3-5, each channel may be defined by substantially parallel channel walls (e.g. channel walls 148, 348) extending from a channel bottom (such as the SSR mounting platform 304 or an additional plate). Accordingly, the channels can be open along a length of the channel (e.g., along a side of the channel) to allow pre-encapsulated heating cable to be more easily inserted into the channel. In other embodiments, channels can be configured differently. For example, a channel may include channel walls that are not parallel to one another, or the channel may be enclosed so as to only be open at each end of the channel.

Relatedly, channel walls may be formed of a material suitable for heat transfer, such as aluminum or another metal. It should be noted that other heater assemblies not specifically discussed herein, incorporating channels configured to receive pre-encapsulated heating cables, may also be contemplated within the scope of various embodiments of the invention. Furthermore, while the examples described herein generally refer to pre-encapsulated heating cables, it should be noted that such examples also apply to cartridge heaters and other types of resistive heating elements.

In order to transfer heat from a resistive heating element (e.g. resistive heating cables 160A, 260A, 360A) to a heater assembly, a resistive heating element can be potted in a respective channel with a heat transfer medium, for example, a two-component polyurethane (PU) compound or another suitable compound. For example, with particular reference to FIG. 3, the resistive heating cable 160A can be positioned within the interior space 144 of the channel 140 (i.e., between the channel walls 148) and a potting compound (e.g., a PU compound) is poured into the channel 140 over the resistive heating cable 160A, then left to cure. After curing, the resistive heating cables 160A are thereby secured within the channel 140.

However, according to some aspects of the invention, resistive heating elements (e.g., resistive heating cables 160A, 260A, 360A) can also be pre-encapsulated with a potting compound (e.g., a PU compound) and then inserted into a respective channel, thus eliminating the need for in-channel potting and curing, as described above. More specifically, as will described in further detail below, prior to installation within a channel, one or more lengths (e.g. portions or sections) of a resistive heating element can be encapsulated with PU compound and cured, forming an encapsulating PU block, for example, encapsulating blocks 160B, 260B, 360B.

An encapsulating block can be sized to correlate with dimensions of a corresponding channel (e.g., channels 140, 240, 340). More specifically, at least a width of an encapsulating block can be sized to be slightly larger than a width of the corresponding channel. For example, with reference to FIG. 5, a ratio of a dimension of the encapsulating block 360B (e.g., a width) to a corresponding dimension of the channel 340 (e.g. a width taken between channel walls 348) can range from 1.05 to 1.25, 1.01 to 1.10, or 1.01 to 1.05.

Accordingly, as shown in FIG. 5, when the encapsulating block 360B is pushed into the channel 340, the encapsulating block 360B is compressed into the channel 340 to create a press- or interference-fit coupling. This interference-fit can provide increased contact between the encapsulating block 360B and walls of the channel 340 for increased heat transfer from the resistive heating cables 360A to the channel walls 348 through the encapsulating block 360B. Additionally, in some embodiments, a length of the encapsulating block 360B may be substantially equivalent to a length of the channel 340, and a height of the encapsulating block 360B may be substantially equivalent to or larger than a height (i.e., depth) of the channel 340 such that an installed encapsulating block 360B can extend out of the channel 340, as shown in FIG. 5.

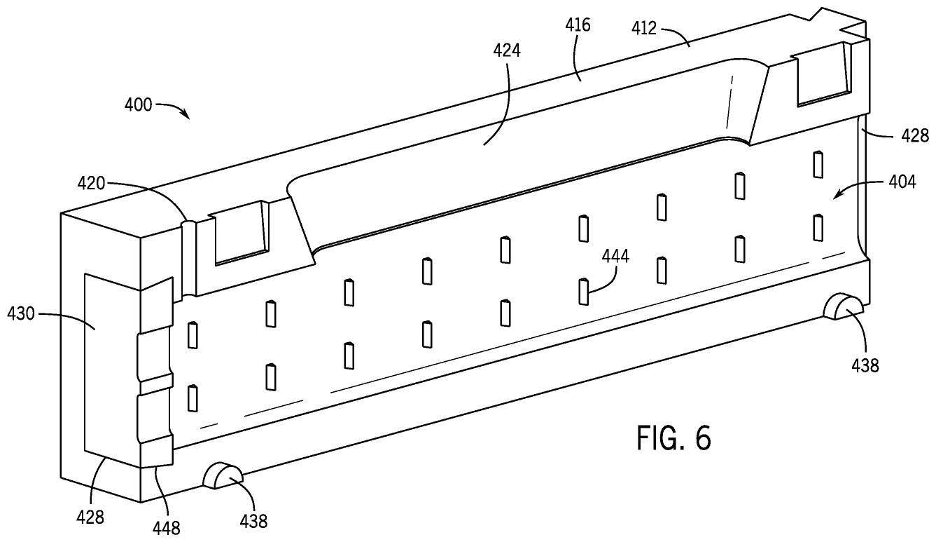

In some embodiments, portions of resistive heating elements (e.g., resistive heating cables) may be pre-encapsulated with PU compound using a mold. For example, FIGS. 6-10 illustrate an example mold 400, which can be used to encapsulate one or more portions of one or more resistive heating elements. As illustrated, the mold 400 is configured to produce the pre-encapsulated heating cable 360 for the heater assembly 300. That is, the mold 400 is configured to form the encapsulating blocks 360B that form the encapsulated portions of the resistive heating cables 360A of the pre-encapsulated heating cable 360. However, aspects of the discussion relating to the mold 400 are equally applicable to other molds configured to form other pre-encapsulated heating elements, for example, the pre-encapsulated heating cables 160, 260 of the heater assemblies 100, 200, respectively.

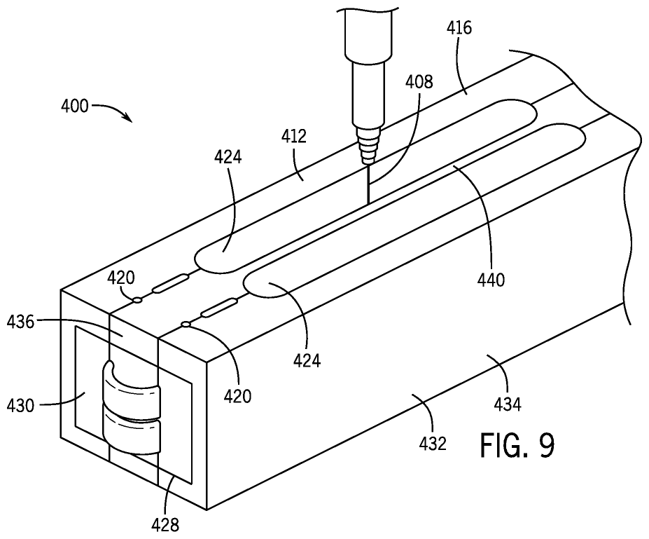

In general, the mold 400 can define a cavity 404 (e.g., an enclosed cavity) that can be configured to contain the one or more portions of the resistive heating cables 360A that are to be surrounded by a potting compound 408 (e.g., a two-component PU thermal potting compound, as shown in FIG. 9), which can be poured into the mold 400 and then cured within the mold 400 to form the encapsulating blocks 360B. In this regard, the enclosed cavity 404 defines a negative space that corresponds with the desired shape of the encapsulating blocks 360B.

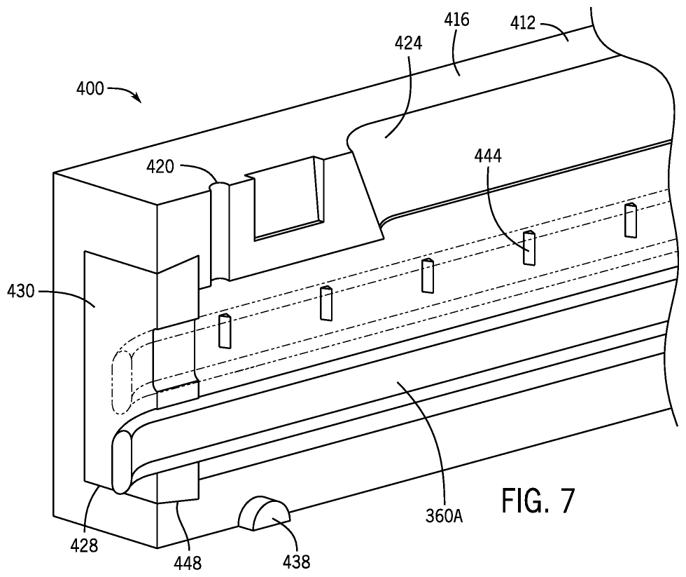

The mold 400 can be configured as a multi-part mold. In particular, FIGS. 6 and 7 illustrate a first mold part 412 of the mold 400, which can include a body 416 forming part of a cavity 404 in communication with a bleed hole 420, an inlet hole 424, and two end holes 428. The two end holes 428 can each be configured to receive a sealing insert 430 (e.g., a rubber sealing insert). The first mold part 412 defines a portion (e.g., a half) of each of the cavity 404, the bleed hole 420, the inlet hole 424, and the end holes 428. Correspondingly, the mold 400 can include a second, mating mold part 432 (as shown in FIG. 9) that may be a substantial mirror image of the first mold part 412, or that may be configured differently from the first mold part 412. As illustrated, the second mold part 432 is a mirror image of the first mold part 412. Accordingly, the second mold part 432 includes a body 434 that defines a corresponding portion (e.g., half) of each of the cavity 404, the bleed hole 420, the inlet hole 424, and the end holes 428. As a result, when the first mold part 412 and the second mold part 432 are matingly engaged, the full cavity 404, bleed hole 420, inlet hole 424, and end holes 428 may be defined by the mold 400 (i.e., the first and second mold parts 412, 432, collectively). In some cases, a mold part can include alignment features (i.e., structures) that can help to align the various mold parts with one another so that they may be matingly engaged. For example, the first mold part 412 includes pins 438, which can be received by recesses formed in an opposing mold part (e.g., the second mold part 432).

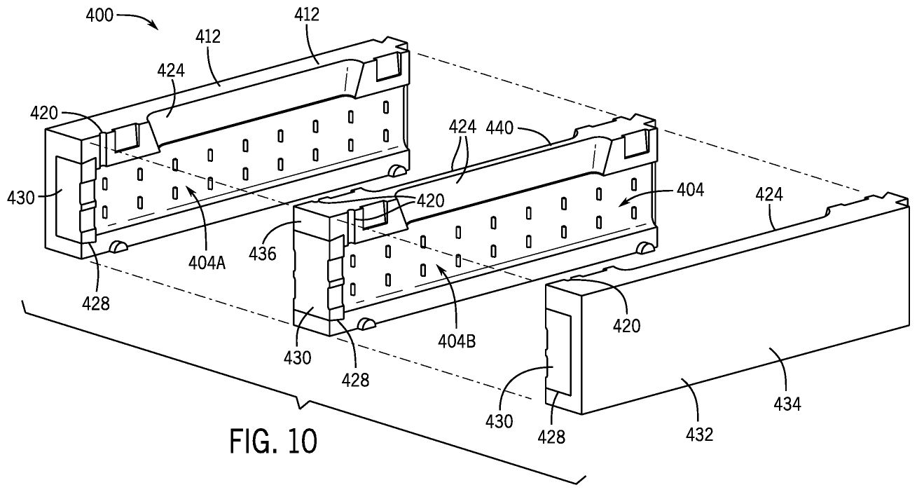

Additionally, in some embodiments, for example, referring to FIGS. 9 and 10, the mold 400 can include an intermediary mold part 436 in addition to the first mold part 412 and the second mold part 432. The intermediary mold part 436 can include a body 440 with a partially defined cavity 404, bleed hole 420, inlet hole 424, and end holes 428 on either side of the body 440. As a result, when the intermediary mold part 436 is matingly engaged between the first mold part 412 and the second mold part 432, a first cavity 404A, with a respective bleed hole 420, inlet hole 424, and end holes 428 is formed, as well as a second cavity 404B, with a respective bleed hole 420, inlet hole 424, and end holes 428. In other embodiments, additional mold parts can be provided and arranged to provide additional cavities for a mold.

As shown in FIGS. 7, 9 and 10, one or more resistive heating cables 360A can be routed through the cavity 404 so as to extend out from the end holes 428. Accordingly, only a portion (e.g., a length or section) of the resistive heating cables 360A sits in the cavity 404. In that regard, the cavity 404 can further include one or more positioning elements 444 (e.g., pins or other protrusions) that can be configured to support the resistive heating cables 360A at a desired position within the cavity 404. Also, as shown in FIGS. 6, 7, and 9, ends of the body 416 can include end recesses 448 adjacent the end holes 428, each of which can be configured to receive a sealing insert 430 (e.g., a rubber sealing insert) that can receive an end of the resistive heating cables 360A outside of the respective end hole 428, which may help maintain positioning of the resistive heating cables 360A within the cavity 404 and seal the end hole 428. For example, the end recesses 448 can have a dovetail-like shape that is widest proximate the cavity 404 and narrows moving outward and away from the cavity 404, which can correspond with a shape of the sealing insert 430. Accordingly, the sealing inserts 430 can be secured within the end recesses 448 to seal the end holes 428 and prevent potting compound 408 from flowing out of the cavity 404.

In some embodiments, the cavity 404 can have a height and a width that is larger than a corresponding height and width of a resistive heating cable 360A in order to permit potting compound 408 to completely encapsulate the portion of the resistive heating cable 360A within the cavity 404, as further described below. Furthermore, a cavity 404 can also be sized to allow for two or more resistive heating cables 360A to be fully encapsulated. For example, in some embodiments, the cavity 404 can have a height that is greater than or equal to double the height of a resistive heating cable 360A in order to accommodate two stacked resistive heating cables 360A (as shown in FIG. 5). However, in other embodiments, the cavity 404 can be sized to accommodate a single resistive heating cable 360A, or more than two resistive heating cables 360A. Relatedly, the width of a cavity 404 can also be configured to allow two or more resistive heating cables 360A to be placed next to each other. Accordingly, the cavity 404 can be configured to accommodate any arrangement of one or more resistive heating cables 360A therein.

More generally, the shape and size of a mold cavity can be correlated with a shape and size of a particular channel of a heater assembly into which a pre-encapsulated heating cable is to be installed. For example, a height of the cavity 404 may correspond to a height of, or slightly larger or smaller (e.g. 5% to 10% larger or smaller) than a height of the respective channels 340. Additionally, in some embodiments, the cavity 404 can include a width slightly larger than a width of the respective channels 340 so that the resulting encapsulating block 360B must compress to fit into the respective channel 340, i.e., creating a press- or interference-fit connection. That is, contact between the channel walls 348 of the respective channel 340 and the encapsulating block 360B causes the channel 340 to compress the encapsulating block 360B. For example, an interference-fit can provide a proper compression ratio of the encapsulating block 360B that results in an optimal heat transfer from the resistive heating cable 360A to the channel walls 348.

When the first mold part 412 and the second mold part 432 (and, optionally, the intermediary mold part 436) are matingly engaged, the cavity 404 may be substantially sealed so that only the inlet hole 424, the bleed hole 420, and the end holes 428 remain open. However, once the resistive heating cables 360A are installed within the cavity 404, the end holes 428 can then be substantially sealed by the sealing inserts 430. For example, as shown in FIG. 10, the two resistive heating cables 360A can be routed through a first cavity 404A formed by the first mold part 412 and the intermediary mold part 436, then curved around and routed through a second cavity 404B formed by the intermediary mold part 436 and the second mold part 432. Accordingly, two portions of each of the resistive heating cables 360A are disposed within a respective cavity 404 (e.g., a first cavity 404A formed by the first mold part 412 and the intermediary mold part 436 and a second cavity 404B formed by the intermediary mold part 436 and the second mold part 432). With the resistive heating cables 360A held in the respective cavities 404A, 404B, the ends of the cavities 404A, 404B can be sealed by the sealing inserts 430. That is the sealing inserts 430 seal between the mold 400 and the heating cables 22.

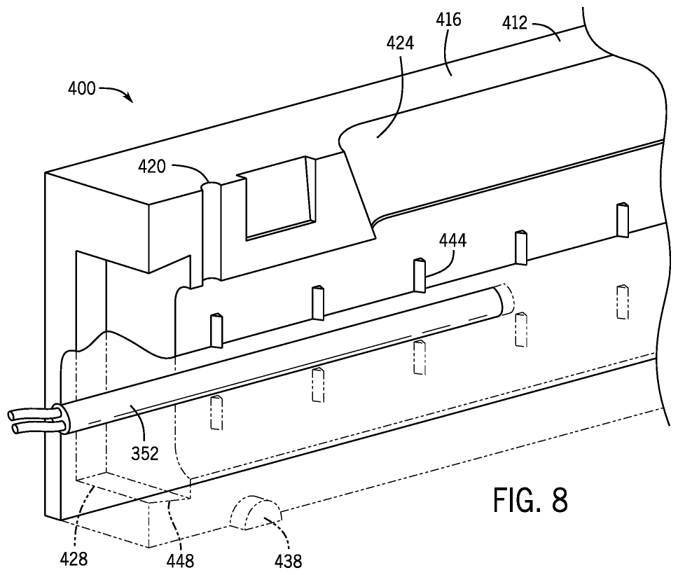

When a portion of each of the resistive heating cables 360A is sealed within a respective cavity 404, the potting compound 408 (e.g., a liquid PU compound) can be poured into the inlet holes 424, as shown in FIG. 9, thereby filling each respective cavity 404A, 404B with the potting compound 408 and encapsulating the portion of the resistive heating cables 360A therein. As a cavity 404 is being filled, the corresponding bleed holes 420 can provide a relief port for excess potting compound 408 and can allow any air contained within the cavity 404 to be forced out by the potting compound 408. Once filled the resistive heating cables 360A can remain in the mold 400 for a time period sufficient to let the potting compound 408 set (e.g., dry or cure), thereby forming the encapsulating block 360B. In some embodiments, for example, as shown in FIG. 8, the mold 400 can also include a heat source, such as a cartridge heater 452, positioned adjacent the cavity 404 (e.g., behind the cavity 404). The cartridge heater 452 can be operated (i.e., powered by a power source) to increase a curing temperature of the potting compound 408, thus shortening cure time.

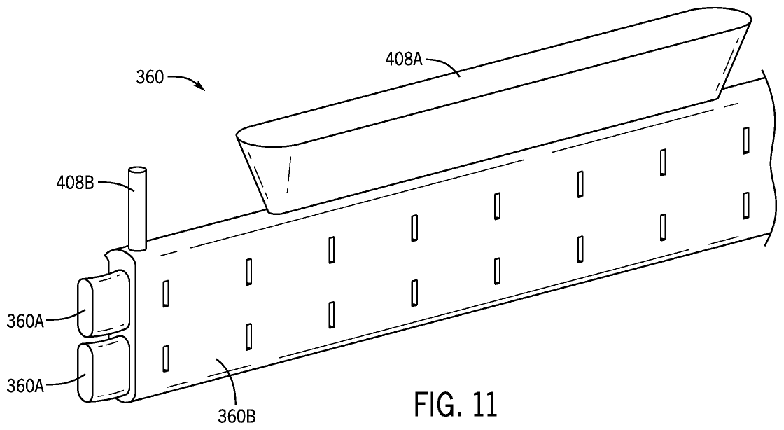

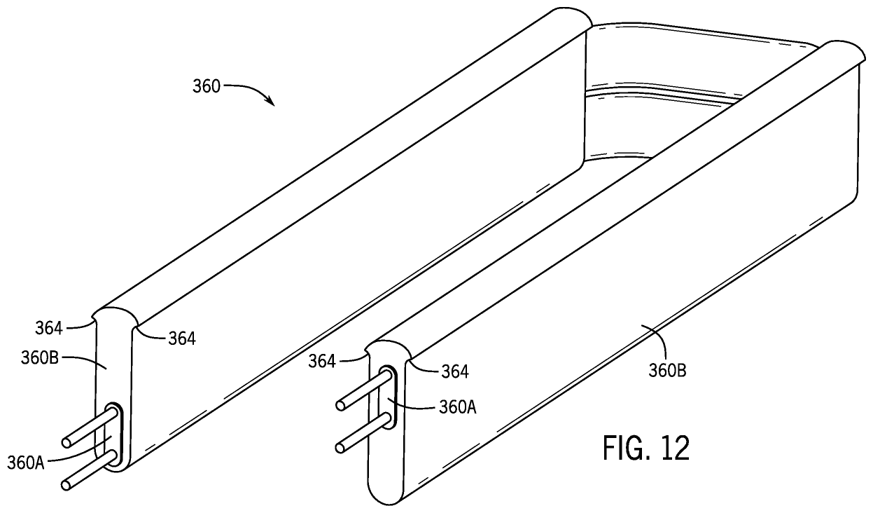

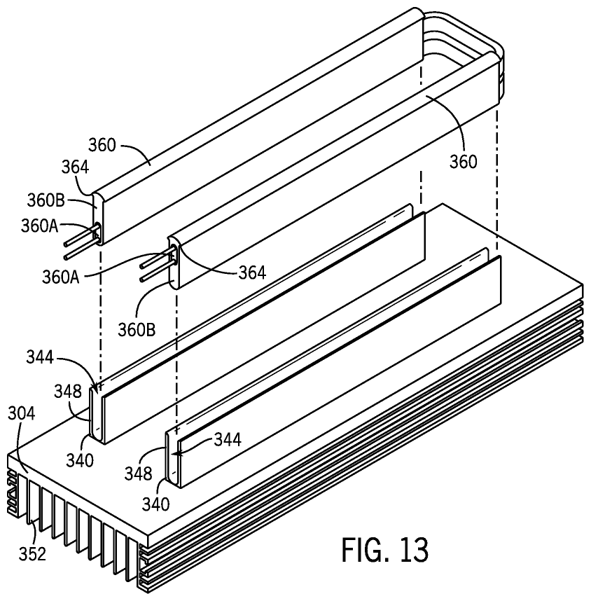

Once the potting compound 408 is cured, the mold parts 412, 432, 436 can be disengaged from each other to release the resistive heating cables 360A with the encapsulating blocks 360B. In some cases, as illustrated in FIG. 11, the pre-encapsulated heating cable 360 may have excess sections of cured potting compound 408A, 408B resulting from potting compound 408 being disposed and curing within the inlet hole 424 and the bleed hole 420, respectively, which can be removed (e.g., by cutting off). Following removal of any excess pieces of cured potting compound (e.g., potting compound sections 408A, 408B), the final pre-encapsulated heating cable 360 with one or more resistive heating cables 360A and one or more encapsulating blocks 360B, as shown in FIG. 12, can be installed in the heater assembly 300. For example, FIG. 13 illustrates the pre-encapsulated heating cable 360 being installed (e.g., inserted) into channels 340 of the heater assembly 300. Similarly, FIGS. 2-4 illustrate the pre-encapsulated heating cables 160. 260 being installed in the channels 140, 240 of the heater assemblies 100, 200, respectively.

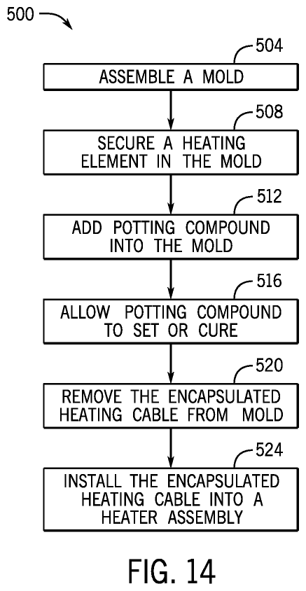

FIG. 14 illustrates a method 500 of producing a pre-encapsulated heating element (i.e., a method of performing an encapsulation process for encapsulating at least a portion of a resistive heating element), according to some embodiments of the invention. While the method 500 is described with reference to the heater assembly 300 and the mold 400, the various steps of the method 500 are also applicable to other heater assemblies (e.g., heater assemblies 100, 200) and other suitable molds. The method 500 can include the step 504 of assembling a mold by joining any mold parts together. For example, with regard to the mold 400 illustrated in FIGS. 9 and 10, the step 504 can include joining the first mold part 412 with the intermediary mold part 436, and further joining the second mold part 432 with the intermediary mold part 436. In some cases, the step 504 of assembling the mold 400 can include cleaning the mold 400 (e.g., removing leftover portions of cured potting compound, no shown) and/or applying a release agent to the mold 400 to facilitate easy removal of a pre-encapsuled heating cable 360.

The method 500 can also include the step 508 of securing (i.e., routing) one or more heating elements (e.g., resistive heating cables) into and/or through a cavity of a mold. The step of securing the one or more resistive heating elements can be completed before or after the step 504. For example, the resistive heating cables 360A can first be inserted into a first part of the cavity 404 defined by the first mold part 412, after which the first mold part 412 can be joined with another mold part (e.g., the second mold part 432 or the intermediary mold part 436) to define a cavity 404. Alternatively, the first mold part 412 can be joined with another mold part (e.g., the second mold part 432 or the intermediary mold part 436) to define a cavity 404, after which the resistive heating cables 360A can be inserted into the cavity 404 (i.e., into the mold 400) via end holes 428 or another hole formed in the mold 400. In either case, the step 508 of securing the resistive heating cables 360A in the mold 400 can also include inserting sealing inserts 430 into any end holes 428, to form a seal between the resistive heating cables 360A and the mold 400. Further, the step 508 of securing the resistive heating cables 360A in the mold 400 can include engaging resistive heating cables 360A with one or more positioning elements 444 of the mold 400.

At step 512, potting compound can be added to a mold. For example, the potting compound 408 or other encapsulating (i.e., potting) material, preferably with high thermal conductivity, can be added into the cavity 404 of the mold 400. More specifically, a liquid potting compound 408 can be poured into an inlet hole 424 of the mold 400 to encapsulate the portion of the heating cable 22 that is disposed within the cavity 404. In general, the potting compound 408 can be poured into the cavity 404 via the inlet hole 424 until the potting compound 408 begins to flow out a bleed hole 420 formed in the mold 400. The potting compound 408 flowing out of the bleed hole 420 can serve as an indication that the potting compound 408 has filled any remaining space within the cavity 404, such that the resistive heating cables 360A are completely encapsulated (i.e., surrounded) by the potting compound 408. In other embodiments, a predetermined volume of potting compound 408 can be added into the cavity 404 to ensure proper encapsulation of the heating cable 22.

Continuing, at step 516, potting compound or another encapsulating material, can be allowed to set or cure within a mold. In particular, the potting compound 408 can be allowed to cure with the cavity 404 of the mold 400. In this way, the potting compound 408 can solidify within the mold 400 to form the encapsulating block 360B that encapsulates the resistive heating cables 360A. The amount of time allotted for setting or curing can vary depending on the specific implementation. In that regard, in some embodiments, the step 516 can further include the step of applying heat to the mold 400, which may reduce the curing or setting time. Heat may be applied to the mold from an external heat source, for example, by the cartridge heater 452 (see FIG. 8) that can be coupled to the mold 400. In other embodiments, heat may be applied to the mold 400 so that the mold 400 reaches a minimum curing temperature to allow curing to commence.

At step 520, a pre-encapsulated heating element can be removed from a mold, that is, having cured the potting compound 408 to form the encapsulating block 360B, the now encapsulated resistive heating cable 360A (i.e., the pre-encapsulated heating cable 360) can be removed from the mold 400 at step 520. In particular, to remove the pre-encapsulated heating cable 360 from the mold 400, the various mold components can be disassembled. For example, with regard to the mold 400 illustrated in FIGS. 9 and 10, the sealing inserts 430 can be removed from the mold 400 and each of the first mold part 412 and the second mold part 432 can be separated from the intermediary mold part 436. Accordingly, the pre-encapsulated heating cable 360 will be released from the mold 400, in that it can be removed from mold 400.

In some cases, the step 516 of releasing a pre-encapsulated heating element from a mold can include the step of removing any excess cured potting compound from an encapsulating block. For example, with reference to FIG. 11, cured potting compound sections 408A, 408B, which are formed from potting compound 408 curing within each of the bleed hole 420 and the inlet hole 424, respectively, can be removed from the encapsulating block 360B.

As a result, the pre-encapsulated heating cable 360 will be a stand-alone piece ready for use in the heater assembly 300. That is, the pre-encapsulated heating cable 360 can be installed into the channels 340 of the heater assembly 300 at step 524. For example, as illustrated in FIG. 12, the pre-encapsulated heating cable 360 can be installed into the channels 340 of the heater assembly 300. In some cases, as mentioned above, there may be a press- or interference-fit between the channel walls 348 of the channels 340 and the pre-encapsulated heating cable 360. Accordingly, a force may be applied to the pre-encapsulated heating cable 360 by the channel walls 348, which can act to compress the corresponding encapsulating blocks 360B to cause the pre-encapsulated heating cable 360 to be received within the channels 340. The force applied to the pre-encapsulated heating cable 360 is sufficient to overcome any friction between the pre-encapsulated heating cable 360 and the channel walls 348, as the encapsulating block 360B is compressed by the channel walls 348.

In some embodiments, the mold cavity 404 can be shaped to form, for example, the lip 364 on either side of the encapsulating block 360B, as shown in FIGS. 5 and 12. As a result, the encapsulating block 360B can be pressed into the channel 340 until the lip 364 rests upon or otherwise contacts a portion (e.g., an upper edge) of a channel wall 348, as shown in FIG. 5. The pre-encapsulated heating cable 360 can then be connected to a suitable power source to provide heat to the heater assembly 300.

The method 500 of encapsulating at least a portion of a heating cable for use in a heating assembly, as described above, can improve the manufacturability of the heater assemblies, for example, compared to previous pot-in-place methods. In particular, pre-encapsulating heating cables with encapsulating blocks can form a tight (i.e., press or interference) fit when inserted into a heater assembly (e.g., into channels of a heater assembly) and can, therefore, transfer more heat from the resistive heating element to the heater assembly's heat sink when compared to “dry” contacts between a heating cable surface and a heat sink. The method 500 (i.e., solid pre-encapsulation process) also provides a clean and easy install once a heater assembly is ready to receive pre-encapsulated heating cables, or if heating cables need to be replaced in an existing heater assembly. More specifically, in existing pot-in-place processes, potting compound tends to leak over the top of and out the sides of the channels, whereas a pre-encapsulated heating cable provides a clean, aesthetically pleasing installation, which can eliminate leakage of potting compound onto a heater assembly. Additionally, by using a mold equipped with a cartridge heater or another heat source, curing time for the potting compound can be reduced, thus improving manufacturing cycle time and reducing a necessary number of molds to support production capacity. Furthermore, the method 500 requires less floor space, as only the molds need to take up floor space during potting compound cure times, in comparison to an entire heater assembly. Correspondingly, according to some embodiments, pre-encapsulated heating cables can be manufactured and stored as separate heating cable subcomponents, and then quickly installed on heater assemblies.

In light of the above, embodiments of the invention provide a cable encapsulation process and pre-encapsulated heating cables that can be easily routed through channels of heater assemblies. While the above methods and pre-encapsulated heating cables are described above with respect to heater assemblies, for example, for electronics enclosures, the methods and heating cables can further be incorporated into any application where a heater assembly with an embedded heating cable is utilized. For example, in other embodiments, the pre-encapsulated heating cables can be used in heated walkway panels or paver systems that incorporate routed heating cables.

It will be appreciated by those skilled in the art that while the invention has been described above in connection with particular embodiments and examples, the invention is not necessarily so limited, and that numerous other embodiments, examples, uses, modifications and departures from the embodiments, examples and uses are intended to be encompassed by the claims attached hereto. The entire disclosure of each patent and publication cited herein is incorporated by reference, as if each such patent or publication were individually incorporated by reference herein. Various features and advantages of the invention are set forth in the following claims.

1. A heater assembly for heating an electrical device, the heater assembly comprising:
a channel defining an interior space; and
a pre-encapsulated heating element including a resistive heating element having a pre-encapsulated portion that is surrounded by a block of potting compound, the pre-encapsulated portion being configured to be received with the interior space of the channel.

2. The heater assembly of claim 1, wherein the channel defines channel width and the pre-encapsulated portion defines a pre-encapsulated heating element width, and a ratio of the pre-encapsulated heating element width to the channel width is between 1.01 and 1.05.

3. The heater assembly of claim 2, wherein an interference fit between the pre-encapsulated portion and the channel causes the pre-encapsulated portion to be compressed by the channel so that the pre-encapsulated heating element is secured within the channel.

4. The heater assembly of claim 1, the channel includes opposing parallel sides that define the interior space of the channel.

5. The heater assembly of claim 4, wherein the channel has a U-shaped cross-section.

6. The heater assembly of claim 1, wherein the potting compound is a thermal transfer compound that is configured to transfer heat from the resistive heating element to the channel to heat the electrical device.

7. The heater assembly of claim 6, wherein the potting compound is two-part polyurethane compound.

8. The heater assembly of claim 1, wherein the resistive heating element is configured as a heating cable.

9. The heater assembly of claim 8, wherein the heating cable is self-regulating heating cable or constant wattage heating cable.

10. The heater assembly of claim 1, wherein the resistive heating element is a cartridge heater.

11. The heater assembly of claim 1, wherein the resistive heat element is a plurality of resistive heating elements.

12. The heater assembly of claim 1, wherein the channel is one of a plurality of channels and the pre-encapsulated heating element includes a plurality of pre-encapsulated portions.

13. The heater assembly of claim 12, wherein each of the plurality of pre-encapsulated portions is received within a corresponding channel of the plurality of channels.

14. A method of producing a pre-encapsulated heating element for a heater assembly, the method comprising:
assembling a mold that defines a cavity;
coupling a first mold part defining a first portion of the cavity and a second mold part defining a second portion of the cavity;
securing a portion of a resistive heating element within the cavity;
inserting a sealing insert into an end hole of the mold to position the resistive heating element within the mold;
adding a potting compound to the mold to surround the portion of the resistive heating element that is secured within the mold;
allowing the potting compound to cure to form an encapsulated portion of the pre-encapsulated heating element; and
removing the encapsulated portion from the mold.

15. The method of claim 14 further comprising removing any excess portions of cured potting compound from the encapsulated portion.

16. The method of claim 14, and further comprising applying heat to the mold to cure the potting compound.

17. The method of claim 16, and further comprising providing a mold heating element configured as a cartridge heater to apply heat to the mold.

18. The method of claim 14, and further comprising adding potting compound to the mold through a bleed hole until the potting compound begins to flow out of the cavity through the bleed hole.

19. The method of claim 14, and further comprising providing a cavity with a width that is larger than a corresponding width of a channel of the heater assembly.

20. A heater assembly comprising:
a plurality of channels, each channel of the plurality of channels defining a channel width; and
a pre-encapsulated heating element including a resistive heating element having a plurality of encapsulated portions each surrounded by a block of potting compound, each of the encapsulated portions being received within a corresponding channel of the plurality of channels and defining an encapsulated portion width, the encapsulated portion width being greater than the channel width of the corresponding channel.
